(19) United States
(12) Patent Application Publication
(10) Pub. No.: US 2026/0371508 A1
(43) Pub. Date: Nov. 19, 2026

(54) POWER CONVERSION DEVICE

(71) Applicant: LG INNOTEK CO., LTD., Seoul (KR)

(72) Inventors: Ji Hwan JEON, Seoul (KR); Dong Keun YOON, Seoul (KR); Jae Yeop JUNG, Seoul (KR)

(73) Assignee: LG INNOTEK CO., LTD., Seoul (KR)

(21) Appl. No.: 19/133,980

(22) PCT Filed: Nov. 30, 2023
(86) PCT No.: PCT/KR2023/019615

§ 371 Date: May 29, 2025

(30) Foreign Application Priority Data
Nov. 30, 2022 (KR) 10-2022-0165158

(51) Int. Cl. H05K 5/02; H02M 7/00; H05K 5/00; H05K 7/20

(52) U.S. Cl. CPC H05K 5/0247; H02M 7/003; H05K 5/0069; H05K 7/209

(57) ABSTRACT

This power conversion device comprises a housing, a printed circuit board disposed in the housing, and an electronic component module disposed on one surface of the printed circuit board, the electronic component module comprising: a bracket having a first groove and a second groove formed on the surface facing the printed circuit board; a first core disposed in the first groove; a second core disposed in the second groove; a first cable extending from the first core; and a second cable extending from the second core.

### TECHNICAL FIELDS

The teachings in accordance with exemplary and non-limiting embodiments of the present invention relate generally to a power conversion device.

### BACKGROUND ARTS

Recently, countries around the world have been making various attempts to replace existing fossil energy resources. First of all, they are making intensive investments in the renewable energy industry and the energy distribution and storage industry to improve energy efficiency and use more environmentally friendly energy. In Korea, too, various policies for the energy industry are being planned and implemented in the wake of the nuclear power plant shutdown and power outages caused by the earthquake in Japan. Given this trend, Not only is the demand for renewable energy increasing, but technologies for efficiently managing power, such as smart grids, are also being actively researched.

The issue of using energy efficiently leads to the analysis of demand patterns, such as the location and time of the user using the energy, and the core concept of smart grids is to distribute energy produced considering the user's demand patterns.

Therefore, in order to store the generated energy for a certain period of time or in a certain space and supply it according to the user's usage pattern, a storage device, i.e. a battery, is needed for the generated energy to stay in. The concept of expanding these batteries is the Energy Storage System (ESS).

An energy storage system (ESS) is an energy storage system that controls various voltages/currents generated by distributed power sources or renewable energy and connects them to the power grid as needed or stores idle energy for use. A power conversion system (PCS) is a system that converts the characteristics of electricity, such as AC/DC, voltage, and frequency, in order to receive power from the power source in the energy storage system (ESS) and store it in the battery or release it to the grid.

The power conversion device is shaped by a housing, and a number of electronic components for driving the power conversion device are placed inside the housing. The number of electronic components is electrically connected to each other. For example, the number of electronic components can be interconnected through wiring. According to the above structure, there is a difficulty in placing electronic components considering the electrical connections in the narrow space inside the housing.

### DETAILED DESCRIPTION OF THE INVENTION

### Technical Subject

This embodiment is intended to provide a power conversion device that can compactly connect multiple electronic components to each other and improve assembly.

### Technical Solution

A power conversion device according to an exemplary embodiment of the present invention may comprise: a housing; a printed circuit board disposed in the housing; and an electronic component module disposed on one surface of the printed circuit board, wherein the electronic component module may include: a bracket having a first groove and a second groove formed on the surface facing the printed circuit board; a first core disposed in the first groove; a second core disposed in the second groove; a first cable extending from the first core; and a second cable extending from the second core.

Preferably, but not necessarily, the bracket may include a compartment part that separates the first groove and the second groove, and based on the compartment part, the first groove and the second groove may be spaced apart in the first direction.

Preferably, but not necessarily, the first cable may be provided in multiple numbers, and a first guide for aligning the multiple numbers of the first cable may be disposed on the upper surface of the bracket facing the printed circuit board.

Preferably, but not necessarily, the upper surface of the bracket may be formed with a first guide coupling groove in a staircased manner compared to other areas, and coupled by the first guide, wherein the first guide may be disposed so that at least a portion overlaps the first core in the vertical direction.

Preferably, but not necessarily, the first guide may include a plurality of first through holes through which the plurality of first cables pass, and a first guide protrusion that projects upward from the upper surface of the first guide and couples the first cable on the inside.

Preferably, but not necessarily, the power conversion device may further comprise a hitching part that protrudes from the side of the first guide protrusion to support the first cable.

Preferably, but not necessarily, the second cable may be provided in multiple numbers and may include a second guide disposed on the outside of the second groove to align the multiple second cables.

Preferably, but not necessarily, the second guide may include a first plate part and a second plate part disposed vertically to each other, and a third groove that is coupled by the second plate part may be formed on the outer side of the second groove in the upper surface of the bracket, and the first plate may include a second through hole through which a plurality of second cables passes.

Preferably, but not necessarily, the power conversion device may further comprise a second guide support part that protrudes inwardly from the inner surface of the third groove and supports one surface of the first plate part that faces the third groove.

Preferably, but not necessarily, a packing part may be disposed between the second through hole and the second cable.

### Advantageous Effects

This embodiment has the advantage of being able to miniaturize by placing multiple cores with different functions within a single module.

In particular, there is the advantage that different cables within the module can be easily aligned with each other because multiple cables extending from each of the multiple cores are extended in different directions through the first guide and the second guide.

In addition, the structure of the core and cable fixed through the molding part has the advantage of improving durability.

Furthermore, the connector has the advantage of preventing multiple cables in the device from getting tangled or twisted, allowing them to be easily aligned.

In particular, the buried structure through the cable coupling groove in the connector improves assembly and has the advantage of preventing the cable from protruding into other areas of the housing.

In addition, the increased contact area, cable terminals that take the tension into account, and the coupling structure between the fastening and terminal parts have the advantage of maintaining a stronger coupling force in the electrical connection area.

### BRIEF DESCRIPTION OF DRAWINGS

FIG. 1 is a perspective view illustrating an exterior of a power conversion device according to an embodiment of the present invention.

FIG. 2 is a plane view illustrating an upper surface of a power conversion device according to an embodiment of the present invention.

FIG. 3 is a plane view illustrating a side of a power conversion device according to an embodiment of the present invention.

FIG. 4 is a plane view illustrating a lower surface of a power conversion device according to an embodiment of the present invention.

FIG. 5 is an exploded perspective view of a power conversion device according to an embodiment of the present invention.

FIG. 6 is a drawing showing FIG. 5 from a different angle.

FIG. 7 is a drawing showing FIG. 2 without a printed circuit board.

FIG. 8 is a perspective view illustrating the exterior of an electronic component module according to an embodiment of the present invention.

FIG. 9 is a schematic view of FIG. 8 from a different angle.

FIG. 10 is a plane view illustrating an upper surface of an electronic component module according to an embodiment of the present invention.

FIG. 11 is a drawing illustrating a coupled structure of multiple cores in the bracket according to an embodiment of the present invention.

FIG. 12 is a drawing illustrating a coupled structure of a bracket, a first guide and a second guide according to an embodiment of the present invention.

FIG. 13 is an exploded perspective view of the electronic component module according to an embodiment of the present invention.

FIG. 14 is a perspective view of a bracket according to an embodiment of the present invention.

FIG. 15 is a drawing illustrating a coupled structure of a first guide and a first cable according to an embodiment of the present invention.

FIG. 16 is a plane view illustrating a coupled structure of the electronic component module and the connector in the housing according to an embodiment of the present invention.

FIG. 17 is a drawing illustrating A-A′ in FIG. 16.

FIG. 18 is a perspective view of exterior of a connector according to an embodiment of the present invention.

FIG. 19 is a drawing illustrating FIG. 18 from a different angle.

FIG. 20 is a plane view illustrating an upper surface of a connector according to an embodiment of the present invention.

FIG. 21 is a drawing illustrating B-B′ of FIG. 20.

FIG. 22 is a perspective view illustrating a coupled structure of a connector and a first cable according to an embodiment of the present invention.

FIG. 23 is a drawing illustrating a coupled structure of the first terminal inside a connector according to an embodiment of the present invention.

FIG. 24 is a cross-sectional view illustrating a coupled structure of a printed circuit board, a connector and a first terminal according to an embodiment of the present invention.

### BEST MODEL

Hereinafter, exemplary embodiments of the present invention will be described in detail with reference to the accompanying drawings.

However, the present invention is not limited to the given exemplary embodiments described, but may be implemented in a variety of different forms, and one or more of components among the exemplary embodiments may be optionally combined or substituted between embodiments within the scope of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,”“coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

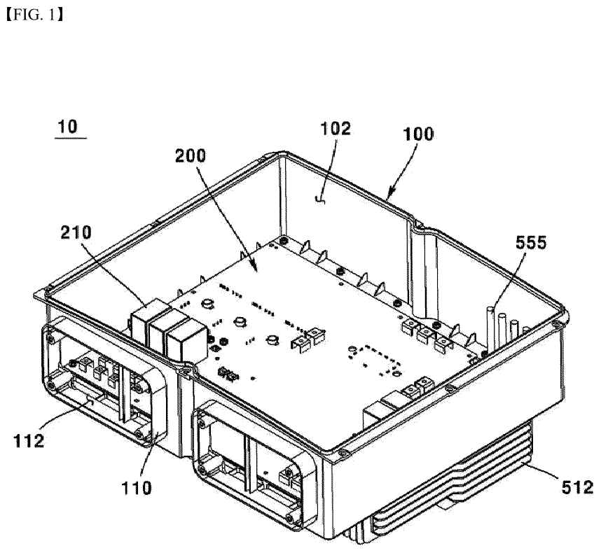

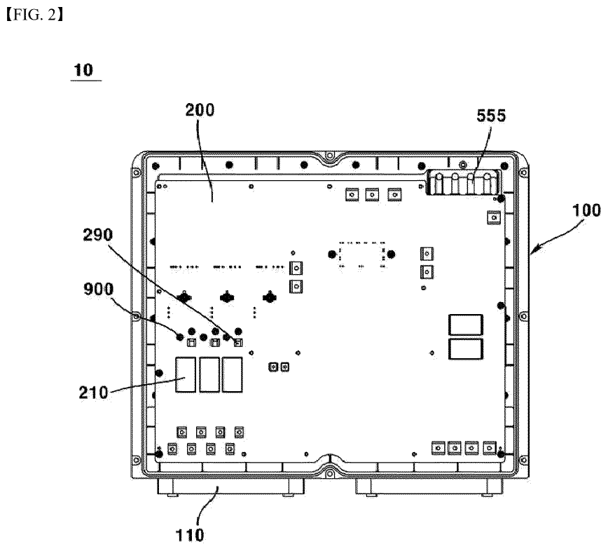

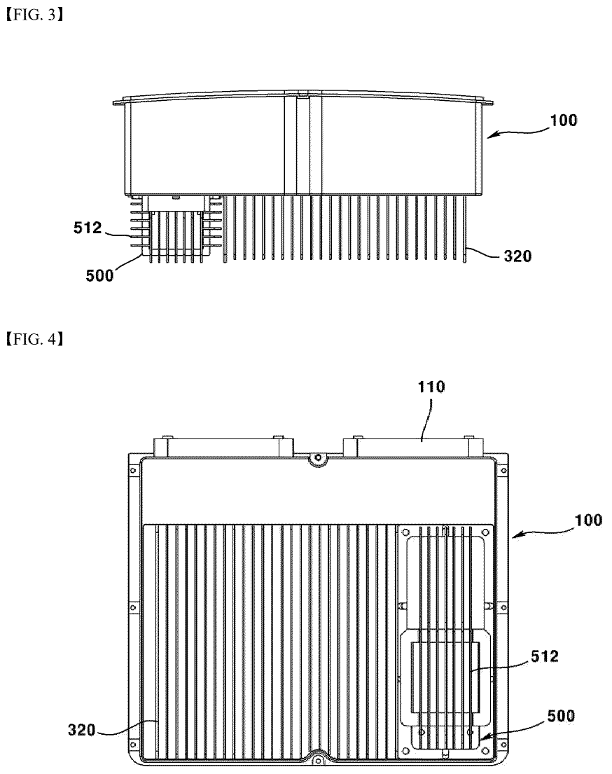

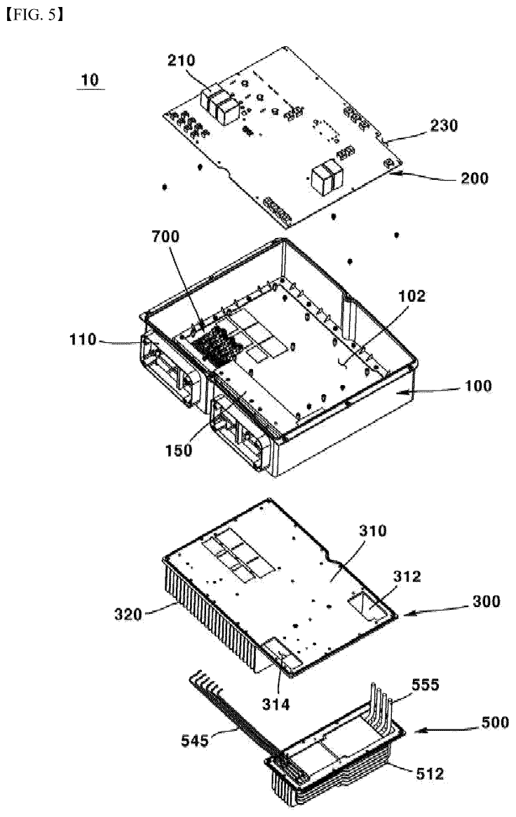

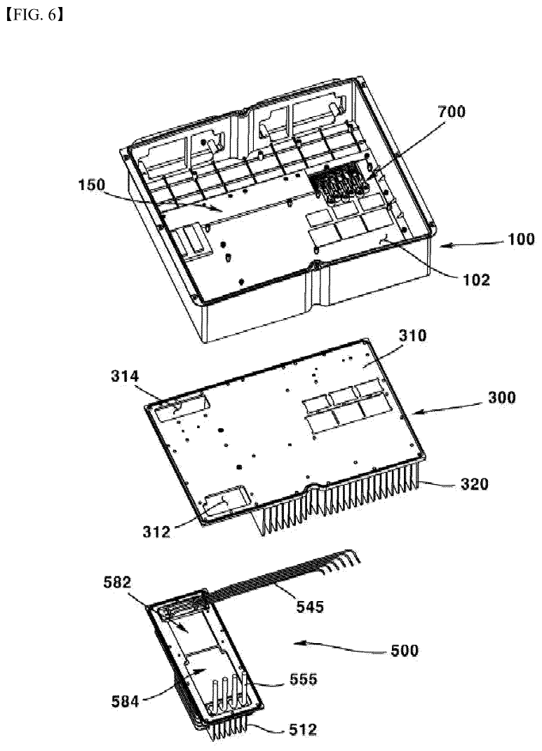

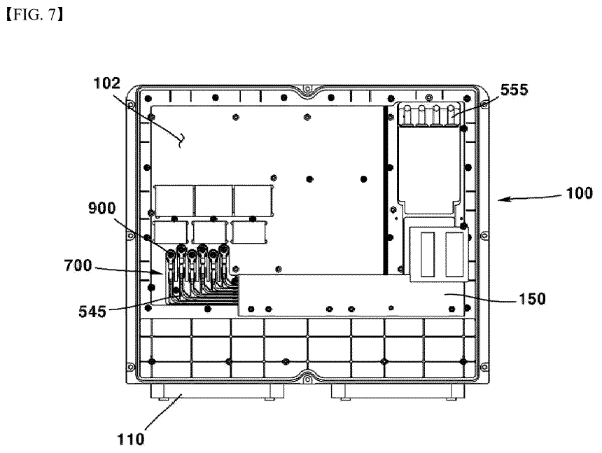

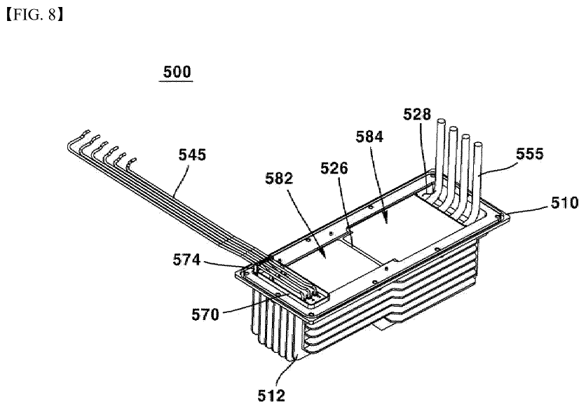

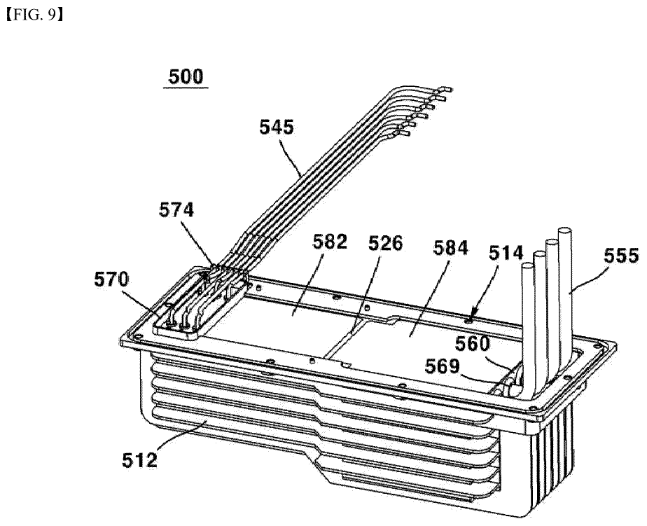

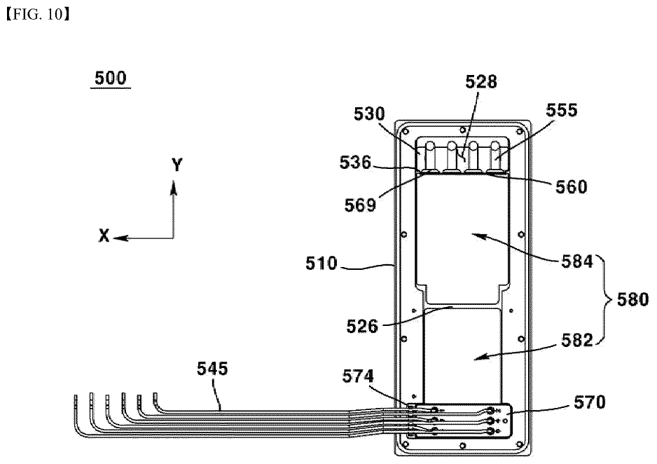

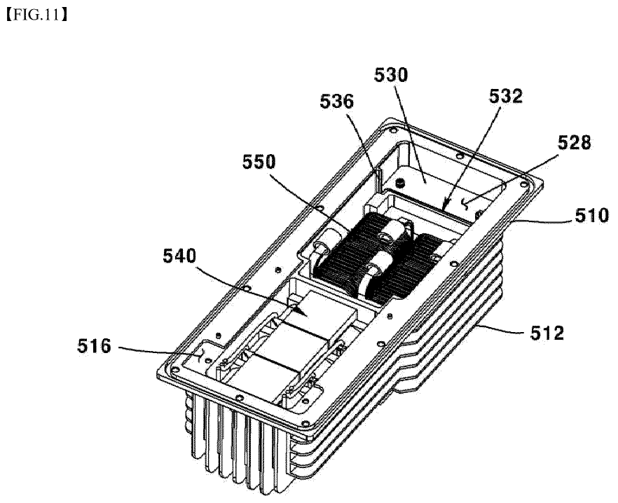

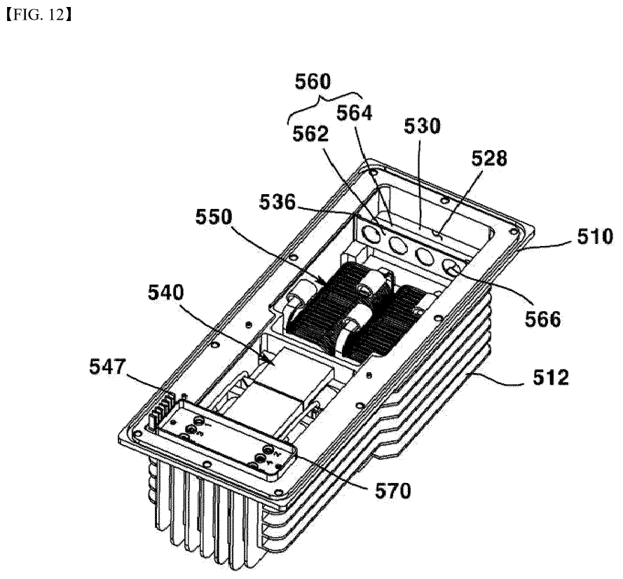

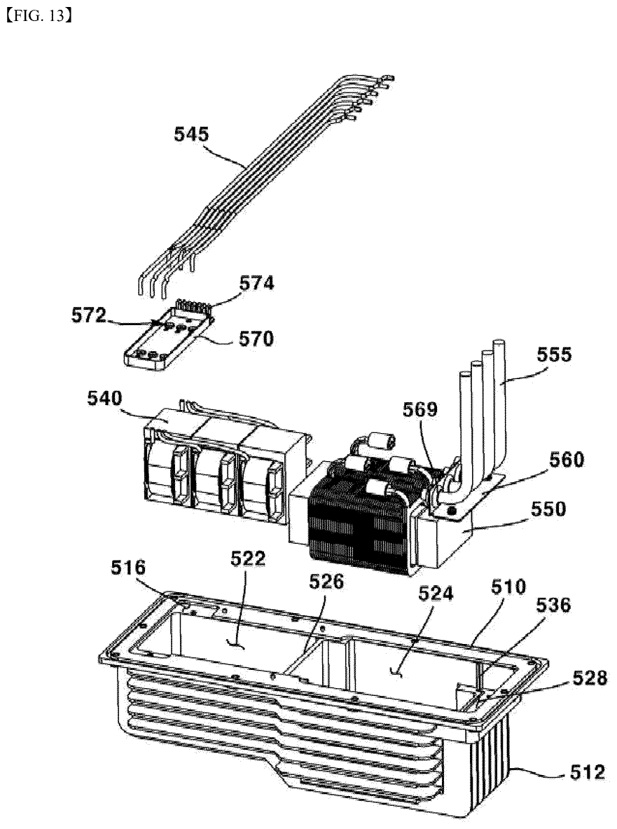

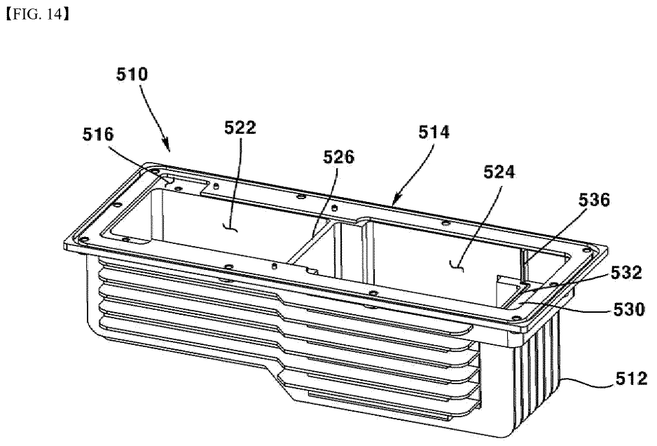

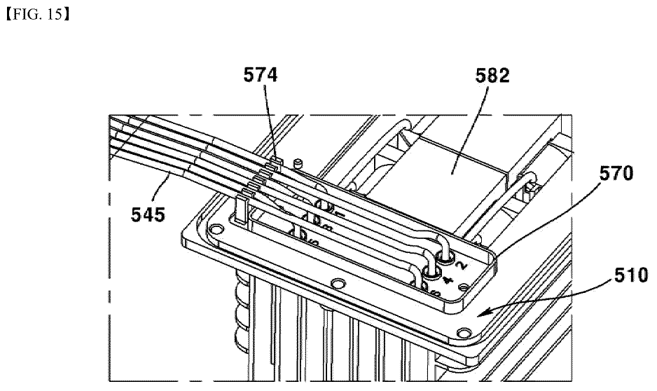

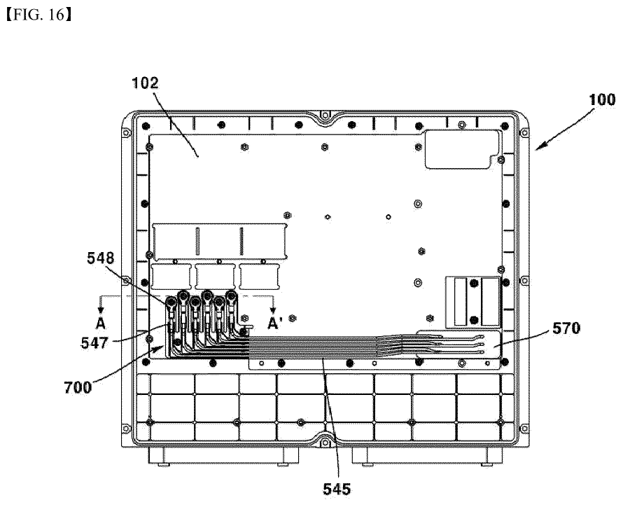

FIG. 1 is a perspective view illustrating an exterior of a power conversion device according to an embodiment of the present invention, FIG. 2 is a plane view illustrating an upper surface of a power conversion device according to an embodiment of the present invention, FIG. 3 is a plane view illustrating a side of a power conversion device according to an embodiment of the present invention, FIG. 4 is a plane view illustrating a lower surface of a power conversion device according to an embodiment of the present invention, FIG. 5 is an exploded perspective view of a power conversion device according to an embodiment of the present invention, FIG. 6 is a drawing showing FIG. 5 from a different angle, FIG. 7 is a drawing showing FIG. 2 without a printed circuit board, FIG. 8 is a perspective view illustrating the exterior of an electronic component module according to an embodiment of the present invention, FIG. 9 is a schematic view of FIG. 8 from a different angle, FIG. 10 is a plane view illustrating an upper surface of an electronic component module according to an embodiment of the present invention, FIG. 11 is a drawing illustrating a coupled structure of multiple cores in the bracket according to an embodiment of the present invention, FIG. 12 is a drawing illustrating a coupled structure of a bracket, a first guide and a second guide according to an embodiment of the present invention, FIG. 13 is an exploded perspective view of the electronic component module according to an embodiment of the present invention, FIG. 14 is a perspective view of a bracket according to an embodiment of the present invention, and FIG. 15 is a drawing illustrating a coupled structure of a first guide and a first cable according to an embodiment of the present invention.

Referring to FIGS. 1 to 7, a power conversion device (10) according to an embodiment of the present invention may include a housing (100), a printed circuit board (200), a cover (300), and an electronic component module (500).

The housing (100) may be formed in the shape of a box with an opening on the upper surface. A space (102) may be formed in the housing (100) to accommodate the printed circuit board (200) and the electronic component module (500). The upper surface of the space (102) may be opened upward. A separate cover (not shown) is provided on the upper surface of the housing (100) so that the upper surface of the space (102) can be covered.

A connector coupling part (110) may be disposed on the side of the housing (100). A hole (112) may be formed in the connector coupling part (110) so that a connector (not shown) for coupling with an external terminal is arranged. The connector coupling part (110) may be provided with multiple connectors. Through the connection of the connector and the external terminal, power can be supplied to the power conversion device (10), or power converted by the power conversion device (10) can be supplied to the external terminal.

The housing (100) may be formed of metal or plastic.

The housing (100) may include a bottom plate and a plurality of side plates. The upper surface of the bottom plate may form the bottom surface of the space (102). The side plate may be arranged to extend upward from the edge of the bottom plate and may form the side of the power conversion device. The bottom plate may be omitted. In this case, the upper surface of the cover (300) may be arranged to form the bottom surface of the space (102).

The printed circuit board (200) may be disposed in the space (102). On the surface of the printed circuit board (200), a number of electronic components (210) for driving the power conversion device (10) may be disposed. For example, on the upper or lower surface of the printed circuit board (200), an MCU (Micro Controller Unit) element or a number of switching elements for controlling the power conversion device (10) may be disposed.

The printed circuit board (200) may have a rectangular cross-sectional shape. The printed circuit board (200) may be disposed on the upper side of the cover (300) and the electronic component module (500). A spacer or guide for fixing the printed circuit board (200) may be disposed on the inner surface of the housing (100). The lower surface of the printed circuit board (200) may be disposed at a predetermined distance (spaced apart) from the bottom surface of the space (102).

The printed circuit board (200) may include a cable hole (230). The cable hole (230) may be shaped to penetrate the lower surface of the printed circuit board (200) from the upper surface. The cable hole (230) may be disposed at one corner of the printed circuit board (200). The cable hole (230) may be disposed to allow a second cable (555) described below to pass through.

The printed circuit board (200) may include an assembly hole (290, see FIG. 2). The assembly hole (290) may be disposed adjacent to the fastening member (900) to be described later. The assembly hole (290) may be disposed adjacent to one corner of the printed circuit board (200) in which the cable hole (230) is formed, and the other corner opposite to the corner in which the cable hole (230) is formed, with respect to the center of the printed circuit board (200). The assembly hole (290) may have a rectangular cross-section. Through the assembly hole (290), the worker can check the coupled state of the fastening member (900) and the connector (700) that will be described later in the assembly process of the power conversion device (10). The assembly hole (290) may be provided in multiple numbers and may be disposed being spaced apart from each other.

The cover (300) may be disposed at the lower portion of the housing (100). The cover (300) may be coupled to the lower surface of the housing (100). The cover (300) may be coupled to the bottom plate of the housing (100). The lower surface of the housing (100) may be screwed to the cover (300). As mentioned above, the bottom plate may be omitted. In this case, the upper surface of the cover (300) may form the bottom surface of the space (102).

The cover (300) may include a bottom (floor) plate (310) and a first heat sink (heat dissipation pin, 320). The bottom plate (310) may be coupled to the lower surface of the housing (100). The cross-sectional shape of the bottom plate (310) may be formed to correspond to the cross-sectional shape of the space (102). A first hole (314) and a second hole (312) may be formed in the bottom plate (310). The first hole (314) and the second hole (312) may each be shaped to penetrate the lower surface of the bottom plate (310) from the upper surface. The first hole (314) and the second hole (312) may be spaced apart from each other. The first hole (314) and the second hole (312) may be spaced apart to the first direction. At least a portion of the first cable (545) described below may be disposed in the first hole (314). The first cable (545) may be disposed to pass through the first hole (314). At least a portion of the second cable (555) described below may be disposed in the second hole (312). The second cable (555) may be disposed to pass through the second hole (312).

The first heat sink (320) may be shaped to protrude downward from the lower surface of the bottom plate (310). The first heat sink (320) increases the cross-sectional area of the cover (300), which has the advantage of facilitating the dissipation of heat in the space (102) within the housing (100). The first heat sink (320) may be provided in multiple numbers and may be disposed in a mutually spaced-apart manner in a second direction perpendicular to the first direction. The first heat sink (320) may be arranged so that at least a portion overlaps the printed circuit board (200) in the vertical direction.

The electronic component module (500) may be disposed on the lower surface of the housing (100). The electronic component module (500) may be disposed on the lower surface of the cover (300). The electronic component module (500) may be coupled to the lower surface of the bottom plate (310). The electronic component module (500) may include multiple inductors.

The following provides a detailed description of the electronic component module (500).

Referring to FIGS. 8 to 15, the electronic component module (500) may include a bracket (510), a first core (540), a second core (560), a first cable (545), a second cable (555), a first guide (570), The second guide (560) and the molding part (580).

The bracket (510) may form the outer shape of the electronic component module (500). The bracket (510) may be formed of metal or plastic. The bracket (510) may be coupled to the lower surface of the cover (300). In this case, the first heat sink (320) may not be formed on the lower surface of the cover (300) to which the upper surface of the bracket (510) is coupled. In other words, the first heat sink (320) may be formed on the lower surface of the cover (300) except for the area to which the electronic component module (500) is coupled.

The bracket (510) may be formed in the shape of a box with an open upper surface. The bracket (510) may include a lower plate forming the lower surface and a side plate extending upward from the edge of the lower plate. The side plate may be disposed so that at least a portion overlaps the first heat sink (320) in a horizontal direction. A plurality of second heat sink (512) that protrudes outward may be formed on the outer surface of the bracket (510). The cross-3 sectional area of the outer surface of the bracket (510) is increased through the second heat sink (512), thereby improving the heat dissipation efficiency. The second heat sink (512) may be shaped to protrude outward from the outer surface of the side plate and the outer surface of the lower plate. In this case, the second heat sink (512) protruding from the outer surface of the side plate and the second heat sink (512) protruding from the outer surface of the lower plate may be disposed perpendicularly to each other.

A space may be formed within the bracket (510) in which the first core (540) and the second core (560) are disposed. The space may be in the shape of a groove that is formed by being recessed downward from the upper surface of the bracket (510). The space may be disposed in an overlapping manner with the printed circuit board (200) in the vertical direction. The space may include a first groove (522) and a second groove (524). The first groove (522) and the second groove (524) may be disposed in a mutually separable manner with respect to a compartment part (526). The first groove (522) and the second groove (524) may be disposed at a mutually spaced-apart manner with respect to the first direction. The compartment part (526) may have a shape that protrudes upward from the upper surface of the lower plate. The bottom surface of the first groove (522) may be disposed above the bottom surface of the second groove (524).

A number of screw holes (514) may be formed on the upper surface of the bracket (510). The upper surface of the bracket (510) may be screwed to the lower surface of the cover (300) through the screw holes (514). A number of protrusions may be formed on the upper surface of the bracket (510). A protrusion hole may be formed on the lower surface of the cover (300), into which the number of protrusions can be inserted, allowing the cover (300) and the bracket (510) to be coupled together.

A first guide coupling groove (516) may be formed on the upper surface of the bracket (510) so that it is recessed downward relative to other areas. The cross-sectional shape of the first guide coupling groove (516) may be formed corresponding to the cross-sectional shape of the first guide (570). The first guide coupling groove (516) may be disposed on the outside of the first groove (522). The first guide coupling groove (516) may be disposed adjacent to one side end of the bracket (510).

The bracket (510) may include a third groove (528). The third groove (528) may be formed by a depression from the upper surface of the bracket (510) downward relative to other areas. The first groove (522), the second groove (524) and the third groove (528) may be disposed in mutual adjacency with respect to the first direction. The second groove (524) may be disposed between the first groove (522) and the third groove (528).

The bottom surface of the third groove (528) may be disposed above the bottom surface of the first groove (522) and the second groove (524). The bracket (510) may protrude upward from the upper surface of the lower plate, and may include a protrusion (530, see FIG. 14) that forms at least a portion of the bottom surface of the third groove (528). The protrusion (530) may be disposed adjacent to other side end facing one side end of the bracket (510). On the upper surface of the protrusion (530), multiple areas may be formed that are staggered (stair-cased) in the vertical direction. The upper surface of the protrusion (530) may include a first staircase surface and a second staircase surface arranged above the first staircase surface, and the first staircase surface may be disposed closer to the second groove (524) than the second staircase surface.

The bracket (510) may include a second guide support part (536, see FIG. 14). The second guide support part (536) may be formed to protrude inward from the inner surface of the third groove (528). The second guide support part (536) may be provided in multiple numbers and may be disposed facing each other in a second direction perpendicular to the first direction. The second guide support part (536) may be formed to extend in an upward and downward direction from the upper surface of the second staircase surface of the protrusion (530) to the upper surface of the bracket (510). Based on the second guide support part (536), the second groove (524) and the third groove (528) may be partitioned from each other. The second guide support part (536) can support the second guide (560).

A guide groove (532, see FIG. 14) may be formed on the upper surface of the protrusion (530) so that it is recessed downward relative to other areas. The guide groove (532) may be formed so that both ends connect the lower ends of the plurality of second guide support parts (536). The guide groove (532) may have a cross-sectional shape of approximately a ‘ [symbol] ’ character. At least a portion of the second molding part (584) described later may be coupled to the guide groove (532).

The first core (540) may be coupled to the first groove (522). The first core (540) may include an inductor. The first core (540) may be a DC-DC core that converts a DC voltage to a DC voltage. The first core (540) may be provided in multiple numbers and may be disposed in mutual adjacency with respect to the first direction within the first groove (522). For example, the first core (540) may be three.

The electronic component module (500) may include a first cable (545) extending from the first core (540). The first cable (545) may be provided in multiple numbers. For example, the first cable (545) may be six, which is twice the number of the first core (540). In other words, based on a single first core (540), two first cables (545) may be provided. The first cable (545) may be connected at both ends to the first core (540) and the printed circuit board (200), respectively, so that the first core (540) and the printed circuit board (200) can be electrically connected to each other.

The second core (560) may be coupled to the second groove (524). The second core (560) may include an inductor. The second core (560) may be a DC-to-AC core that converts a DC voltage to an AC voltage. The second core (560) may be provided in multiple numbers and may be disposed in the second direction in the second groove (524) in a neighboring manner. For example, the second core (560) can be two.

The electronic component module (500) may include a second cable (555) extending from the second core (560). The second cable (555) may be provided in multiple numbers. For example, the second cable (555) may be four. In other words, based on a single second core (560), the second cable (555) may be provided in two. The second cable (555) may be connected at both ends to the second core (550) and the printed circuit board, respectively, so that the second core (550) and the printed circuit board (200) can be electrically connected to each other. The cross-sectional area of the second cable (555) can be larger than that of the first cable (545).

The area where the first cable (545) is coupled to the printed circuit board (200) and the area where the second cable (555) is coupled to the printed circuit board (200) may be spaced apart from each other. For example, the area where the second cable (555) is coupled to the printed circuit board (200) may be placed adjacent to one corner of the printed circuit board (200). The area where the first cable (545) is coupled to the printed circuit board (200) may be disposed at a corner of the printed circuit board (200) that is opposite to one of the corners. In this case, one corner of the printed circuit board (200) and the other corner of the printed circuit board (200) may not be adjacent. One corner of the printed circuit board (200) and the other corner of the printed circuit board (200) may be disposed facing each other with respect to the center of the printed circuit board (200).

The extension directions of the first cable (545) and the second cable (555) may be disposed perpendicularly to each other from the electronic component module (500). For example, based on FIG. 10, the first cable (545) may be extended in the X-axis direction. In this case, the second cable (555) may be extended in the X-axis direction, the Z-axis direction perpendicular to the Y-axis, or the upward direction of the electronic component module (500).

The first guide (570) may be coupled to the upper surface of the bracket (510). The first guide (570) may be disposed to protrude upward from the cover (300) through the first hole (314) of the cover (300). A portion of the upper surface of the first core (540) may be covered by the first guide (570). The first guide (570) may align the first cable (545) on the electronic component module (500). The first guide (570) may be coupled to the first guide coupling groove (516). The upper surface of the first guide (570) may protrude upward above the upper surface of the bracket (510). The first guide (570) may be screwed to the upper surface of the bracket (510).

The first guide (570) may include a plurality of first through holes (572, see FIG. 13) that penetrate the lower surface from the upper surface. The first through-holes (572) may be provided in a plurality corresponding to the number of the first cables (545). For example, the first through-hole (572) may be six. The plurality of first through-holes (572) may be disposed at a mutually spaced-apart manner from each other. For example, three each of the plurality of first through-holes (572) may be disposed in the first direction. The first through hole (572) may be disposed to allow the first cable (545) to pass therethrough. A sealing member (not shown) may be disposed between the inner surface of the first through-hole (572) and the outer surface of the first cable (545).

The first cable (545), which extends upward through the first through-hole (572), may be bent in the second direction and then extended.

A first guide protrusion (574) that protrudes upward from the upper surface of the first guide (570) may be arranged. The first guide protrusion (574) may be disposed in multiple numbers and spaced apart along the first direction. Accordingly, an area where the first cable (545) is coupled may be formed between two adjacent first guide protrusions (574). If there are six first cables (545), the first guide protrusion (574) may be provided with seven protrusions, which may form six areas for coupling the first cables (545).

On the side of the first guide protrusion (574) forming the coupled area of the first cable (545), there is a hitching part protruding outward more than other areas, which can prevent the first cable (545) from deviating outward when the first cable (545) is coupled. The hitching part may be disposed adjacent to an upper end of the first guide protrusion (574).

The second guide (560) may be disposed between the second groove (524) and the third groove (528). The second guide (560) may be coupled to the upper surface of the protrusion (530). The second guide (560) may be screwed onto the upper surface of the protrusion (530). The second guide (560) can align the second cable (555) on the electronic component module (500).

In detail, the second guide (560) may include a first plate part (562, see FIG. 12) and a second plate part (564). The first plate part (562) and the second plate part (564) may be disposed vertically with respect to each other. The second guide (560) may have a cross-sectional shape of approximately a ‘ [symbol] ’ shape by the first plate part (562) and the second plate part (564).

The first plate part (562) may be disposed perpendicularly to the upper surface of the bracket (510) or the upper surface of the protrusion (530). The first plate part (562) can be supported by the second guide support part (536) at both ends. One side of the first plate part (562) facing the third groove (528) may be in contact with the second guide support part (536).

The first plate part (562) may include a second through-hole (566) that penetrates from one side to the other side. The second through-hole (566) may be provided in multiple numbers corresponding to the number of the second cable (555). For example, the second through-hole (566) may be four. The multiple second through-holes (566) may be disposed at a second direction and spaced apart from each other. The second through-hole (566) may be disposed to allow the second cable (555) to pass therethrough. A ring-shaped packing part (569) may be disposed between the inner surface of the second through-hole (566) and the outer surface of the second cable (555). Accordingly, the coupled state of the second cable (555) can be maintained firmly within the second through hole (566) and external foreign substances can be prevented from entering through the second through hole (566).

The second cable (555) protruding outward through the second through hole (566) may be bent upward and then extended. In this case, the second cable (555) may be disposed to pass through a cable hole (230) of the printed circuit board (200). In addition, the second cable (555) may be disposed to penetrate the second hole (312) of the cover (300).

The second plate part (564) may be formed to extend horizontally from a lower end of the first plate part (562). The second plate part (564) may be screwed to the bottom surface of the third groove (528). The second plate part (564) may be disposed to cover the guide groove (532).

The molding part (580) may be formed in the first groove (522) and the second groove (524). The molding part (580) may be formed by injecting and hardening the molding liquid into the first groove (522) and the second groove (524). Accordingly, the first core (540) and the second core (550) can be firmly fixed in the first groove (522) and the second groove (524), respectively. The molding part (580) may include a first molding part (582) disposed in the first groove (522) and a second molding part (584) disposed in the second groove (524). At least a portion of the second molding part (584) may be accommodated in the guide groove (532). The first molding part (582) may be coupled with the first guide (570). The second molding part (584) may be coupled with the second guide (560).

Meanwhile, during the formation of the second molding part (584), the support structure of the first plate part (562) and the second guide support part (536) can prevent the first plate part (562) from being pushed in the first direction toward the third groove (528). In addition, the packing part (569) can prevent the molten material for forming the second molding part (584) from flowing outwards.

Meanwhile, in order to prevent the occurrence of electrical noise, a shielding member (not shown) may be disposed between the upper surface of the electronic component module (500) and the lower surface of the printed circuit board (200). The shielding member is formed in the shape of a plate and may be disposed to overlap the first core (540) and the second core (550) in the vertical direction.

According to the above structure, there is an advantage in miniaturizing by placing multiple cores with different functions within a single module.

In particular, there is an advantage in that different cables within the module can be easily aligned with each other because multiple cables extending from each of the multiple cores are extended in different directions through the first guide and the second guide.

In addition, the structure of fixing the core and cables through the molding part has the advantage of improving durability.

The following describes the coupled structure of the printed circuit board (200) and the electronic component module (500) through the first cable (555) in the power conversion device (10) according to the present embodiment.

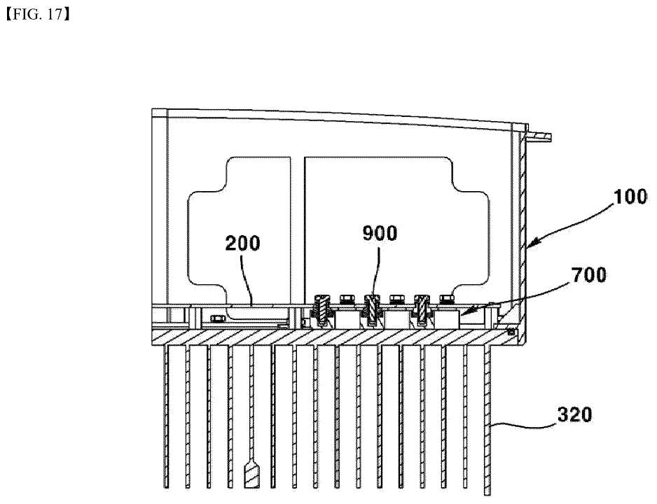

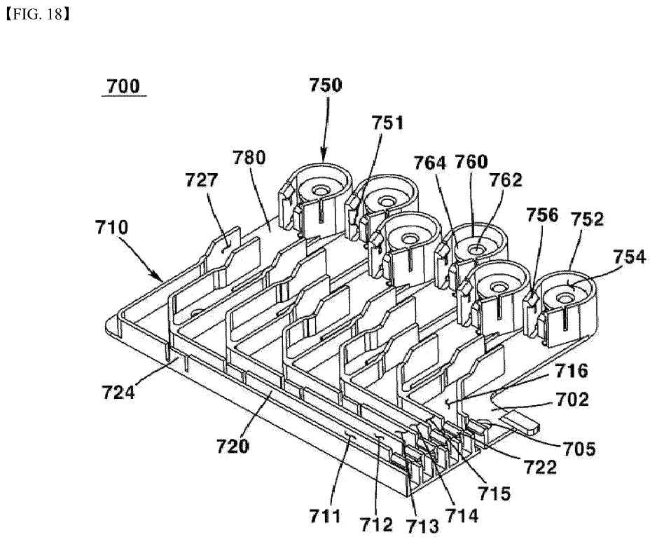

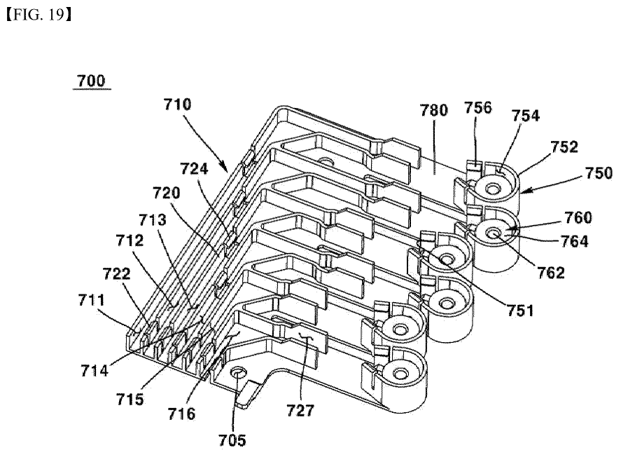

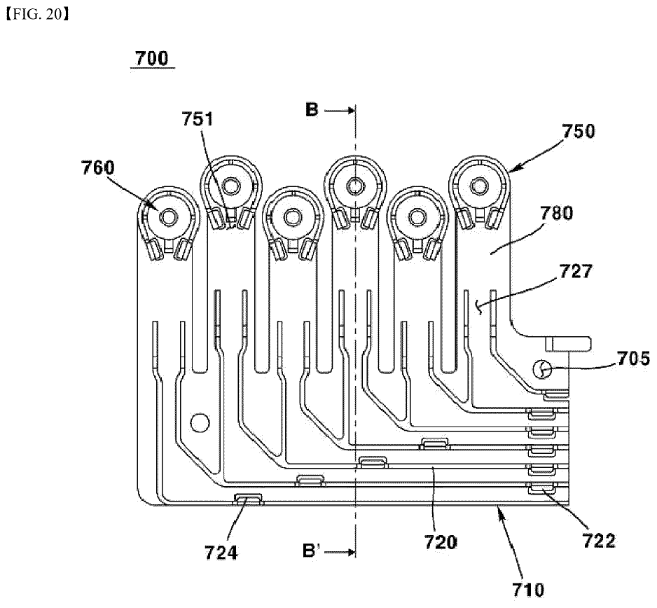

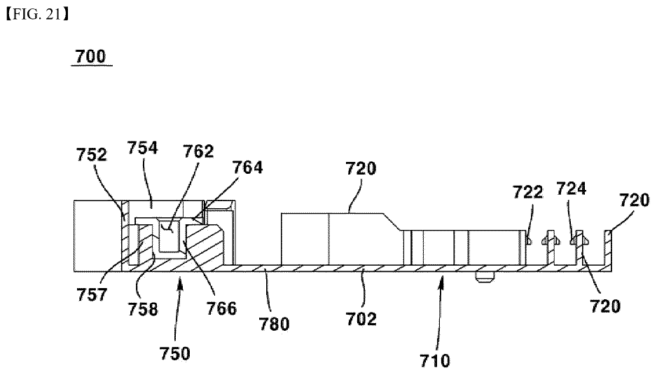

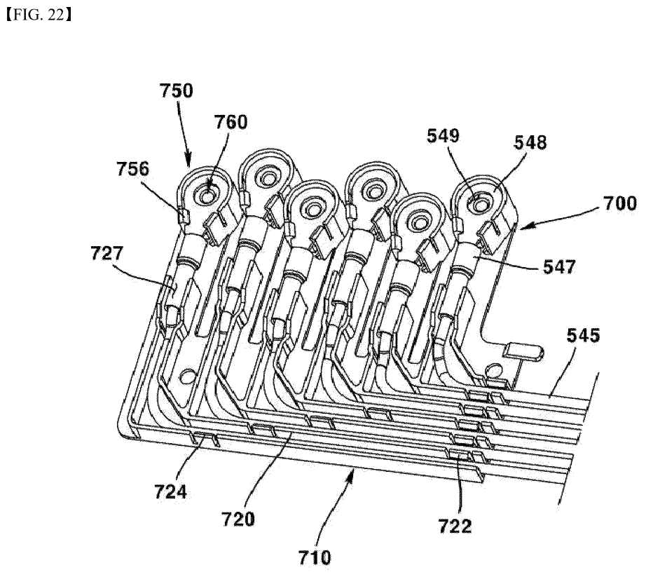

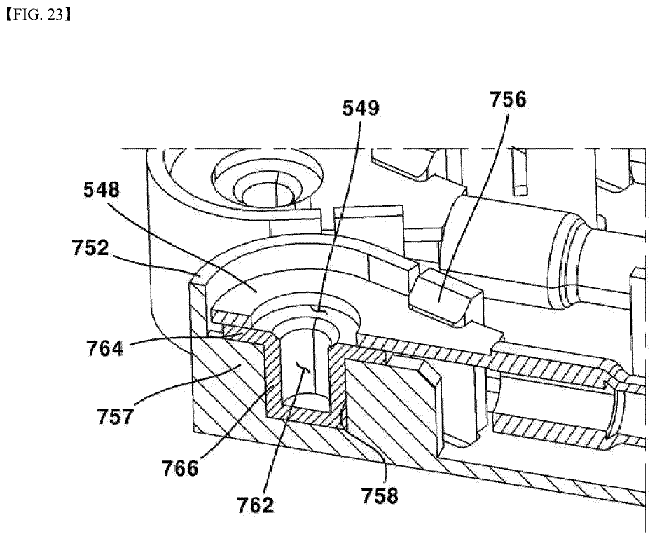

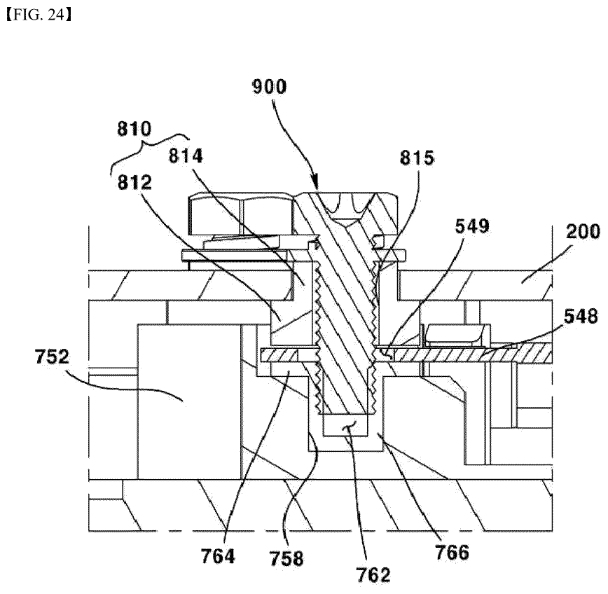

FIG. 16 is a plane view illustrating a coupled structure of the electronic component module and the connector in the housing according to an embodiment of the present invention, FIG. 17 is a drawing illustrating A-A′ in FIG. 16, FIG. 18 is a perspective view of exterior of a connector according to an embodiment of the present invention, FIG. 19 is a drawing illustrating FIG. 18 from a different angle, FIG. 20 is a plane view illustrating an upper surface of a connector according to an embodiment of the present invention, FIG. 21 is a drawing illustrating B-B′ of FIG. 20, FIG. 22 is a perspective view illustrating a coupled structure of a connector and a first cable according to an embodiment of the present invention, FIG. 23 is a drawing illustrating a coupled structure of the first terminal inside a connector according to an embodiment of the present invention, and FIG. 24 is a cross-sectional view illustrating a coupled structure of a printed circuit board, a connector and a first terminal according to an embodiment of the present invention.

As mentioned above, the electronic component module (500) may be electrically connected to the printed circuit board (200) via the first cable (545) and the second cable (555), as shown in FIGS. 16 to 24. In this case, the coupled area of the first cable (545) and the second cable (555) on the printed circuit board (200) may be one corner and the other corner, which are respectively disposed opposite to each other with respect to the center of the printed circuit board (200).

As shown in FIG. 16, a plurality of the first cables (545) may be aligned through the first guide (570) and extended to an area that overlaps one corner of the printed circuit board (200) in the vertical direction. In this case, the plurality of first cables (545) may be aligned so that they do not get tangled with each other and have a constant distance from each other through the first guide protrusion (574) of the first guide (570).

A shielding member (150) may be disposed between the cable (545) and the printed circuit board (200). The shielding member (150) may be formed in the shape of a plate, and may be arranged to overlap in the vertical direction between one end of the first cable (545) coupled with the electronic component module (500) and the other end of the first cable (545) coupled with the connector (700) described later. Accordingly, it is possible to prevent electrical noise from occurring between the printed circuit board (200) and the first cable (545).

The power conversion device (10) may include a connector (700) for connecting a plurality of the first cables (545) to the printed circuit board (200) by arranging them. The connector (700) may be disposed between the printed circuit board (200) and the cover (300). The connector (700) may be coupled to the upper surface of the bottom plate of the housing (100). The connector (700) may be screwed to the upper surface of the bottom plate of the housing (100). In some cases, the connector (700) may be screwed to the upper surface of the cover (300). The connector (700) may be disposed so that it overlaps at least a portion of the printed circuit board (200) in the vertical direction.

When the four corner areas of the printed circuit board (200) are divided and referred to as a first corner, a second corner adjacent to the first corner, a third corner adjacent to the second corner, and a fourth corner adjacent to the first corner, the connector (700) may be disposed adjacent to the first corner, the electronic component module (500) may be disposed adjacent to the second corner, and the second cable (555) may be dispose adjacent to the third corner. In this case, the first cable (545) may be disposed to connect the first corner and the second corner.

The connector (700) may include a holder, a fastening part (760), and a terminal part (810).

The holder may form the outer shape of the connector (700). The holder may be screwed to the bottom plate of the housing (100) or to the upper surface of the cover (300). The holder may include screw holes (705) for screwing. The screw holes (705) may be disposed in multiple numbers and may be spaced apart at a distance from each other.

The holder may include a first area (710), a second area (750) and a connection area (780) connecting the first area (710) and the second area (750). The holder may have a shape in which the guide part (720) and the coupling part (752) described below are arranged on the plate-shaped base (702). The holder may be formed of plastic material.

Based on the direction in which the first cable (755) extends from the electronic component module (500), the first area (710) may be disposed at one end of the connector (700). The first area (710) may include a guide part (720) that protrudes upward from the upper surface of the base (702). The guide part (720) may have a fence shape. The guide part (720) may be provided in multiple numbers and may be disposed at a mutually spaced-apart distance based on the arrangement direction of the first cable (545). A cable coupling groove may be formed between two adjacent guide parts (720) into which the first cable (545) is coupled.

When the first cable (545) is provided with six cables, including the first-1 cable, the first-2 cable, the first-3 cable, the first-4 cable, the first-5 cable, and the first-6 cable, the cable coupling groove may include a first-1 cable coupling groove (711) into which the first-1 cable is coupled, and a second cable coupling groove (712) into which the first-2 cable is coupled, a first-1 cable coupling groove (713) into which the first-3 cable is coupled, a fourth cable coupling groove (714) into which the first-4 cable is coupled, a fifth cable coupling groove (715) into which the first-5 cable is coupled, and a sixth cable coupling groove (716) into which the first-6 cable is coupled.

The cable coupling groove may have at least one bent area. Accordingly, the cable coupling groove may be divided into multiple areas. The multiple areas of the cable coupling groove may be disposed perpendicularly to each other.

To maintain a secure coupled state of the first cable (545) in the cable coupling groove, the first area (710) may include a plurality of guide protrusions (722, 724). The plurality of guide protrusions (722, 744) may have a shape that protrudes from the side of the guide part (720). The guide protrusion (722, 744) may contact the outer surface of the first cable (545). The plurality of guide protrusions (722, 744) may include a first guide protrusion (722) disposed at one end of the cable coupling groove, and a second guide protrusion (724) disposed between one end of the cable coupling groove and the other end. Based on a single cable coupling groove, the guide part (720) in which the first guide protrusion (722) is formed and the guide portion (720) in which the second guide protrusion (724) is formed may be different.

An extension part (727) may be formed at the other end of the cable coupling groove facing the second area (750). The extension part (727) may be formed wider than the other areas. The extension part (727) may be formed for each cable coupling groove. In this case, the adjacent extension parts (727) may be spaced apart from each other. The plurality of coupling grooves may be spaced apart by as much as the thickness of the guide part (720) in the area where the guide protrusions (722, 724) are formed, and may be spaced apart by a greater distance in the area where the expansion portion (727) is formed.

As shown in FIG. 22, a ring-shaped cable terminal (548) may be formed at a distal end of the first cable (545) for coupling with the printed circuit board (200). The cable terminal (548) may be formed to correspond to the cross-sectional shape of the coupling groove (754) in the coupling part (752) described later. The cable terminal (548) may include a hole (549) through which the screw (900) described later can pass. The diameter of the hole (549) of the cable terminal (548) may be larger than the diameter of the screw (900) fastening area. The cable terminal (548) may be made of metal.

A sheathing area (547) having a larger cross-sectional area than other areas may be disposed in the area adjacent to the cable terminal (548) on the outer surface of the first cable (545). The sheathing area (547) may be coupled to the extension part (727).

Based on the direction in which the first cable (755) extends from the electronic component module (500), the second area (750) may be disposed at the other end of the connector (700). The second area (750) may include a coupling part (752) that protrudes upward from the upper surface of the base (702). The coupling part (752) may have a circular or elliptical cross-sectional shape with one side open that faces the first area (710). The cable terminal (548) of the first cable (545) may be coupled to the coupling part (752). A coupling groove (754) may be formed on the inner side of the coupling part (752) so that the cable terminal (548) can be coupled.

An opening (752) may be formed on one side of the coupling part (752). The first cable (545) may be disposed so as to pass through the opening (752). At least a portion of the sheathing area (547) or the cable terminal (548) may be disposed in the opening (752).

The coupling part (752) may be provided in a plurality corresponding to the number of the first cable (545). In this case, the plurality of the coupling parts (752) may be disposed in a zigzag shape. Accordingly, each distal end of two adjacent coupling parts (752) among the plurality of coupling parts (752) may have different spaced-apart distances from the first region (710). Accordingly, the size of the arrangement region of the plurality of coupling parts (752) may be smaller.

The second area (750) may include a protrusion (756). The protrusion (756) may have a shape that protrudes inward from the inner surface of the coupling part (752). The protrusion (756) may be provided in multiple numbers, and may be disposed at both distal ends of the coupling part (752) adjacent to the opening (752). The coupling of the cable terminal (548) in the coupling groove (754) can be guided primarily through the protrusions (756).

A protrusion (757, see FIG. 21) may be formed on the bottom surface of the coupling groove (754) formed on the inside of the coupling part (752) in a shape that protrudes upward from other areas. The protrusion (757) is for the fastening part (760) to be coupled, and a groove (758) in the shape of a depression downward from the other areas may be formed on the upper surface. The groove (758) may be formed in the center of the upper surface of the protrusion (757).

The connection area (780) can connect the first area (710) and the second area (780). There may not be any protruding structures on the connection area (780). The sheathing area (547) may be disposed on the connection area (780). Through the connection area (780), the second area (780) can be flexibly supported with respect to the first area (710). Specifically, a pressing force can be generated downward during the screw-fastening process between the fastening part (760), the terminal part (810), and the cable terminal (548) through the screw (900) mentioned later. In this case, the pressing force can be offset by the elasticity of the second area (780) relative to the first area (710) through the connecting area (780).

The fastening part (760) may be disposed in the second area (750). The fastening part (760) may be in contact with the cable terminal (548). The fastening part (760) may be electrically connected to the cable terminal (548). The fastening part (760) may be formed of metal and may be integrally formed with the holder through the insert injection.

The fastening part (760) may include a body (766) into which a groove (758) in coupling part (752) is coupled, and a flange (764) that is bent outward from the upper end of the body (766) and extends therefrom. A threaded hole (762) may be formed in the center of the body (766) into which the screw (900) is screwed. A thread or a thread groove for screwing may be formed on the inside surface of the threaded hole (762).

The flange (764) can support the lower surface of the cable terminal (548). The upper surface of flange (764) and the lower surface of the cable terminal (548) may be in contact. The contact area between the cable terminal (548) and the fastening part (760) can be increased by the flange (764).

The terminal part (810) may be disposed on the lower surface of the printed circuit board (200). The terminal part (810) may be disposed between the cable terminal (548) and the printed circuit board (200). A terminal hole for coupling the terminal part (810) may be formed in the printed circuit board (200). The terminal hole may be provided in a plurality corresponding to the number of the first cable (545). The terminal hole may be shaped to penetrate the lower surface from the upper surface of the printed circuit board. At least a portion of the terminal part (810) may be coupled to the terminal hole.

The terminal part (810) may be soldered to the lower surface of the printed circuit board (200). A circuit pattern (not shown) may be formed on the surface of the printed circuit board (200) to which the terminal part (810) is coupled. The first cable (545) and the printed circuit board (200) may be electrically connected by the contact between the terminal part (810) and the cable terminal (548).

The terminal part (810) may include a plurality of areas having different cross-sectional areas. The terminal part (810) may include an upper area (814) coupled to the terminal hole, and a lower area (812) supporting the lower surface of the printed circuit board (200) and in contact with the cable terminal (548) on the lower surface. The lower area (812) may be formed to be larger than the cross-sectional area of the terminal hole or the upper area (814).

The terminal part (810) may include a hole (815) through which the screw (900) passes. In this case, the hole (815) may not be formed with a thread or a screw groove.

The screw (900) can be threaded into the threaded hole (762) of the fastening part (760) by passing through the hole (815) of the terminal part (810) and the hole (549) of the cable terminal (545). Since the screw (900) is only screwed with the fastening part (760), the second area (750) and the printed circuit board (200) can be pressed together during the process of screwing the screw (900) and the fastening part (760) so that they are close to each other.

Meanwhile, as mentioned above, the printed circuit board (200) may have the assembly hole (290) formed, and the worker can check the assembly status of the printed circuit board (200), the cable terminal (548), and the terminal part (810) through the assembly hole (290).

According to the above structure, it has the advantage of preventing multiple cables in the device from tangling or getting twisted through the connector, allowing them to be easily aligned.

In particular, the buried structure through the cable coupling groove in the connector improves assembly and has the advantage of preventing the cable from protruding into other areas of the housing.

In addition, the increased contact area, cable terminals that take tension into account, and the coupling structure between the fastening and terminal parts have the advantage of maintaining a stronger coupling force in the electrical connection area.

In the above, it is not necessarily limited to this embodiment, even though all components constituting the embodiment of the present invention are described as being combined or operated by combining them into one. In other words, within the scope of the present invention, all of its components may be selectively combined and operated in one or more. In addition, the terms ‘include,’ ‘comprise,’ or ‘have,’ as used above, should be interpreted to mean that the component may be inherent, unless specifically stated otherwise, and not to exclude other components, but to include other components. All terms, including technical or scientific terms, have the same meaning as commonly understood by a person with ordinary skill in the art to which the invention pertains, unless otherwise defined. Terms that are commonly used, such as those defined in dictionaries, should be interpreted consistent with their meaning in the context of the relevant art, and not in an idealized or overly formal sense, unless expressly defined in the invention.

The above description is merely an illustrative example of the technical idea of the present invention, and those skilled in the art in the technical field to which the present invention belongs will be able to make various modifications and variations within the scope that does not deviate from the essential characteristics of the present invention. Therefore, the embodiments disclosed in the present invention are not intended to limit the technical idea of the present invention, but are intended to explain it, and the scope of the technical idea of the present invention is not limited by these embodiments. The scope of protection of the present invention should be interpreted by the following claims, and all technical ideas within the scope of the equivalent thereof should be interpreted as being included in the scope of the present invention.

1-10. (canceled)

11. A power conversion device, comprising:
a housing;
a printed circuit board disposed in the housing; and
an electronic component module disposed to face one surface of the printed circuit board,
wherein the electronic component module includes:
a bracket having a first groove and a second groove formed on a surface facing the printed circuit board;
a first core disposed in the first groove;
a second core disposed in the second groove;
a first cable extending from the first core; and
a second cable extending from the second core.

12. The power conversion device of claim 11, wherein the bracket includes a compartment part that separates the first groove and the second groove, and based on the compartment part, the first groove and the second groove are spaced apart in a first direction.

13. The power conversion device of claim 11, wherein the first cable is provided in multiple numbers, and a first guide for aligning the multiple numbers of the first cable is disposed on an upper surface of the bracket facing the printed circuit board.

14. The power conversion device of claim 13, wherein the upper surface of the bracket is formed with a first guide coupling groove in a staircased manner compared to other areas, and coupled by the first guide, and
wherein the first guide is disposed so that at least a portion thereof overlaps the first core in a vertical direction.

15. The power conversion device of claim 13, wherein the first guide includes a plurality of first through holes through which the plurality of first cables pass, and a first guide protrusion that projects upward from an upper surface of the first guide and couples the first cable on the inside.

16. The power conversion device of claim 11, further comprising a hitching part that protrudes from a side of the first guide protrusion to support the first cable.

17. The power conversion device of claim 11, wherein the second cable is provided in multiple numbers and includes a second guide disposed on an outside of the second groove to align the multiple second cables.

18. The power conversion device of claim 17, wherein the second guide includes a first plate part and a second plate part disposed vertically to each other, and a third groove that is coupled by the second plate part is formed on the outer side of the second groove in the upper surface of the bracket, and the first plate includes a second through hole through which a plurality of second cables passes.

19. The power conversion device of claim 18, comprising a second guide support member protruding inwardly from an inner surface of the third groove and supporting one side of the first plate part facing the third groove.

20. The power conversion device of claim 18, wherein a packing part is disposed between the second through hole and the second cable.

21. The power conversion device of claim 18, wherein a guide groove having a concave shape is arranged on a bottom surface of the third groove, and
wherein at least a part of a molding part is arranged in the guide groove.

22. The power conversion device of claim 11, comprising a first molding part arranged in the first groove, and a second molding part arranged in the second groove.

23. The power conversion device of claim 11, wherein a heat dissipation fin is formed on an outer surface of the bracket.

24. The power conversion device of claim 11, wherein a shielding member is disposed between the printed circuit board and the electronic component module.

25. The power conversion device of claim 11, wherein the first cable extends from the electronic component module in a first direction, and
wherein the second cable extends from the electronic component module in a second direction perpendicular to the first direction.

26. A power conversion device, comprising:
a housing;
a printed circuit board disposed in the housing; and
an electronic component module disposed to face one surface of the printed circuit board,
wherein the electronic component module includes:
a bracket having a first groove formed on a surface facing the printed circuit board;
a first core disposed in the first groove;
a plurality of first cables extending from the first core; and
a connector to which the plurality of first cables are connected,
wherein the connector includes a plurality of cable coupling grooves into which the plurality of first cables are respectively coupled.

27. The power conversion device of claim 26, wherein the plurality of cable coupling grooves have a region that is bent at least once.

28. The power conversion device of claim 26, wherein a first guide for aligning the plurality of first cables is disposed on an upper surface of the bracket facing the printed circuit board.

29. The power conversion device of claim 28, wherein the upper surface of the bracket is formed with a first guide coupling groove in a staircased manner compared to other areas, and coupled by the first guide, and
wherein the first guide is disposed so that at least a portion thereof overlaps the first core in a vertical direction.

30. The power conversion device of claim 28, wherein the first guide includes a plurality of first through holes through which the plurality of first cables pass, and a first guide protrusion that projects upward from an upper surface of the first guide and couples the first cable on the inside.
